(19) United States
(12) Patent Application Publication
(10) Pub. No.: US 2007/0296434 A1
(43) Pub. Date: Dec. 27, 2007

(54) Temperature control method and apparatus and test method and apparatus of semiconductor devices

(75) Inventors: Hiroshi Yamada, Kawasaki (JP); Takashi Morimoto, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/585,284

(22) Filed: Oct. 24, 2006

(30) Foreign Application Priority Data
May 25, 2006 (JP) 2006-145670

(51) Int. Cl. G01R 31/02

(52) U.S. Cl. 324/760

(57) ABSTRACT

An electric power is supplied to a semiconductor device while thermally insulating the semiconductor device by bringing a thermal insulating material into contact with the semiconductor device. An internal temperature of the semiconductor device is raised by internal-heating of the semiconductor device. The thermal insulating material is separated from the semiconductor device when the internal temperature reaches a predetermined temperature.

### BACKGROUND OF THE INVENTION

1. Field of the Invention

The present invention generally relates to a temperature control method and apparatus and a test method and apparatus of semiconductor devices, and, more particularly, to a temperature control method and apparatus and a test method and apparatus of semiconductor devices for adjusting a package temperature of a semiconductor device to an arbitrary setting value.

2. Description of the Related Art

In an inspection of semiconductor devices, it is common to perform an electrical performance test while heating the semiconductor devices like a burn-in test. In the burn-in test, it is common to carry out the test after raising a temperature (junction temperature Tj) of the semiconductor devices to be tested by putting the semiconductor devices in a temperature-controlled chamber.

The method of raising a temperature by putting a semiconductor device in a temperature-controlled chamber is effective to a semiconductor device having a small power consumption and a small self-heating. Semiconductor devices having a small power consumption has a small variation in their self-heating due to a variation in power consumption, and it can be regarded that the junction temperature Tj of the semiconductor devices is equal to a temperature of an atmosphere inside a temperature-controlled chamber.

In recent years, for the purpose of improvement in operation speeds of semiconductor devices, high-densification of the semiconductor devices has been advanced, and a higher frequency as an operation frequency has been used. In association with that, power consumption of semiconductor devices has been increasing more and more. When the power consumption of semiconductor devices is increased, a variation in the power consumption between individual semiconductor devices due to a variation generated in a manufacturing process has become large and remarkable.

When a variation in power consumption of each semiconductor device is large, there is a problem in that, even if an attempt is made to set the junction temperature Tj to a predetermined temperature by putting a plurality of semiconductor devices in a temperature-controlled chamber, one having a larger power consumption (that is, one having a larger self-heating) can be at a predetermined temperature but one having a smaller power consumption 0cannot reach the predetermined temperature or it takes a long time to reach the predetermined temperature.

Then, in order to raise quickly the junction temperature Tj of the semiconductor devices of a smaller power consumption, a method of directly heating is used in which a heater is brought into contact with the semiconductor devices having a smaller power consumption. As the heater for heating the semiconductor devices, an electric resistance heater or a heater using a Pertier effect element can be used (for example, refer to Patent Document 1). That is, the same temperature rise as that of the semiconductor devices having a larger power consumption is obtained by applying heat directly from a heater to a semiconductor device having a smaller power consumption and slow temperature rise.

Patent Document 1: Japanese Laid-Open Patent Application No. 8-70068

However, there may occur the following problems in the method of directly heating a semiconductor device by a heater.

1) An operation voltage of the semiconductor device is low, and, thereby, a noise generated by turning ON/OFF the heater induces errors in operation of a logic circuit of the semiconductor device. Thus, it is difficult to assure an accurate test.

2) Since a thermal resistance between an interior of the semiconductor device and a temperature sensor varies largely between an ON state and an OFF state of the heater, a temperature control accuracy is deteriorated. It is difficult to improve the temperature control accuracy even if an ambient temperature of the semiconductor device, an operation time of the heater and power consumption of the semiconductor device are monitored and controlled.

3) Besides the power supplied to the semiconductor device, a power supplied to the heater is needed, which results in an increase in a running cost of a test apparatus.

### SUMMARY OF THE INVENTION

It is a general object of the present invention to provide a novel and useful temperature control method and apparatus and a novel and useful test method and apparatus, in which the above-mentioned problems are eliminated.

A more specific object of the present invention is to provide a temperature control method and apparatus and a test method and apparatus, which can raise quickly a temperature of a semiconductor device without directly heating the semiconductor device by a heater.

In order to achieve the above-mentioned objects, there is provided according to one aspect of the present invention a temperature control method of a semiconductor device, comprising: supplying an electric power to the semiconductor device while thermally insulating the semiconductor device by bringing a thermal insulating material into contact with the semiconductor device; raising an internal temperature of the semiconductor device by internal-heating of the semiconductor device; and separating the thermal insulating material from the semiconductor device when the internal temperature reaches a predetermined temperature.

In the temperature control method according to the present invention, the internal temperature may be adjusted while cooling the semiconductor device after separating the thermal insulating material from the semiconductor device. The temperature control method according to the present invention may further comprise: pressing a heat sink onto the semiconductor device via a thermal sheet interposed therebetween after separating the thermal insulating material form the semiconductor device; and adjusting the internal temperature by adjusting cooling of the semiconductor device by adjusting a pressure applied to the thermal sheet from the heat sink. The pressure applied to the thermal sheet may be adjusted so that the internal temperature of the semiconductor device is maintained at a setting temperature, and the pressure by the heat sink may be maintained constant after the internal temperature is maintained at the setting temperature.

Additionally, there is provided according another aspect of the present invention a temperature control apparatus of a semiconductor device, comprising: a pressure plate that is movable upward and downward with respect to the semiconductor device and configured to press the semiconductor device to a socket of a test apparatus; a thermal insulating material attached to a surface of the pressure plate facing the semiconductor device; and a heat sink that is movable upward and downward with respect to the semiconductor device and cools the semiconductor device by contacting the semiconductor device.

In the temperature control apparatus according to the present invention, a thermal sheet may be provided on a surface of the heat sink facing the semiconductor device, and the heat sink mat contact and press the semiconductor device via the thermal sheet. The thermal sheet may be a heat transfer member of which heat resistance changes when being elastically deformed by a pressure. The temperature control apparatus according to the present invention may further comprise a cooling fan for air-cooling the heat sink.

Further, there is provided according to another aspect of a test method of a semiconductor device, comprising: supplying an electric power to the semiconductor device while thermally insulating the semiconductor device; raising an internal temperature of the semiconductor device by internal-heating of the semiconductor device; and separating the thermal insulating material from the semiconductor device when the internal temperature reaches a predetermined temperature.

In the test method according to the present invention, the internal temperature may be adjusted while cooling the semiconductor device after separating the thermal insulating material from the semiconductor device. The test method according to the present invention may further comprise: pressing a heat sink onto the semiconductor device via a thermal sheet interposed therebetween after separating the thermal insulating material form the semiconductor device; and adjusting the internal temperature by adjusting cooling of the semiconductor device by adjusting a pressure applied to the thermal sheet from the heat sink. The pressure applied to the thermal sheet may be adjusted so that the internal temperature of the semiconductor device is maintained at a setting temperature, and the pressure by the heat sink may be maintained constant after the internal temperature is maintained at the setting temperature.

Additionally, there is provided according to another aspect of the present invention a test apparatus of a semiconductor device, comprising: a pressure plate that is movable upward and downward with respect to the semiconductor device and configured to press the semiconductor device to a socket of the test apparatus; a thermal insulating material attached to a surface of the pressure plate facing the semiconductor device; and a heat sink that is movable upward and downward with respect to the semiconductor device and cools the semiconductor device by contacting the semiconductor device.

In the test apparatus according to the present invention, a thermal sheet may be provided on a surface of the heat sink facing the semiconductor device, and the heat sink may contact and press the semiconductor device via the thermal sheet. The thermal sheet may be a heat transfer member of which heat resistance changes when being elastically deformed by a pressure. The test apparatus according to the present invention may further comprise a cooling fan for air-cooling the heat sink.

According to the present invention, the internal temperature of the semiconductor device can be rapidly raised by supplying an electric power to the semiconductor device by bringing the thermal insulating material into contact with the semiconductor device. Thus, the internal temperature can be reached to the setting temperature for a short period of time from a start time of the power supply. Since no heater is used for raising the temperature, there is no error occurring in operation of the semiconductor device due to a switching noise of a heater or the like.

Other objects features and advantages of the present invention will become more apparent from the following detailed description when read in conjunction with the accompanying drawings.

### BRIEF DESCRIPTION OF THE DRAWINGS

FIG. 1 is a plan view showing an outline structure of a temperature control apparatus of a semiconductor device according to an embodiment of the present invention;

FIG. 2 is a side view showing an outline structure of the temperature control device shown in FIG. 1;

FIG. 3 is a graph showing a relationship between a pressure and a thermal resistance of a thermal sheet;

FIG. 4 is a graph shows a relationship between an amount of downward movement of a heat sink and a pressure applied to the thermal sheet;

FIG. 5 is a flowchart of a temperature control process of a semiconductor device performed by the temperature control apparatus shown in FIG. 1 and FIG. 2; and

FIG. 6 is a graph showing changes in an inside temperature of a semiconductor device according to the temperature control process.

### DETAILED DESCRIPTION OF THE PREFERRED EMBODIMENTS

A description will now be given, with reference to the drawings, of an embodiment of the present invention.

In an embodiment of the present invention, as a means for raising a junction temperature Tj of a semiconductor device, the semiconductor device is not heated directly but a temperature of a semiconductor device is raised rapidly by positively using self-heating of the semiconductor device. That is, by covering a portion radiating heat, such as a back surface of a semiconductor device that is usually exposed to atmosphere, a heat generated inside the semiconductor device is prevented from being radiated outside, which results in promotion of temperature rise of the semiconductor device.

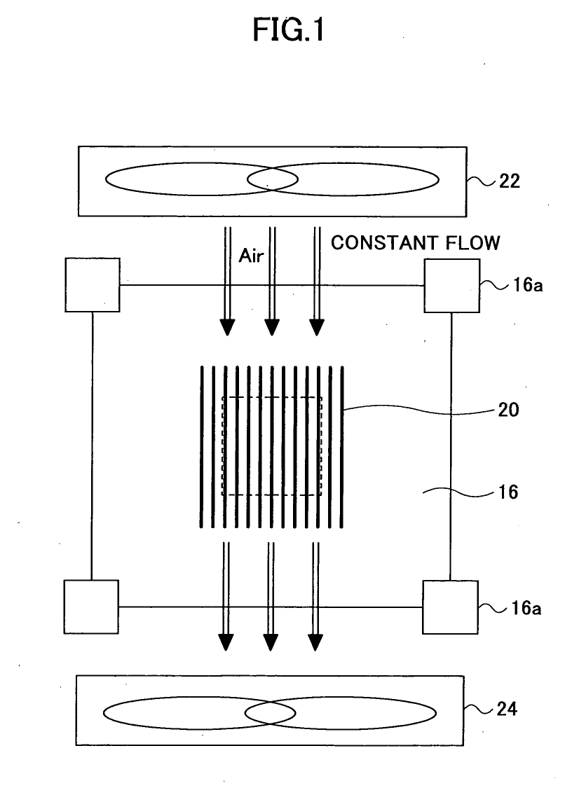

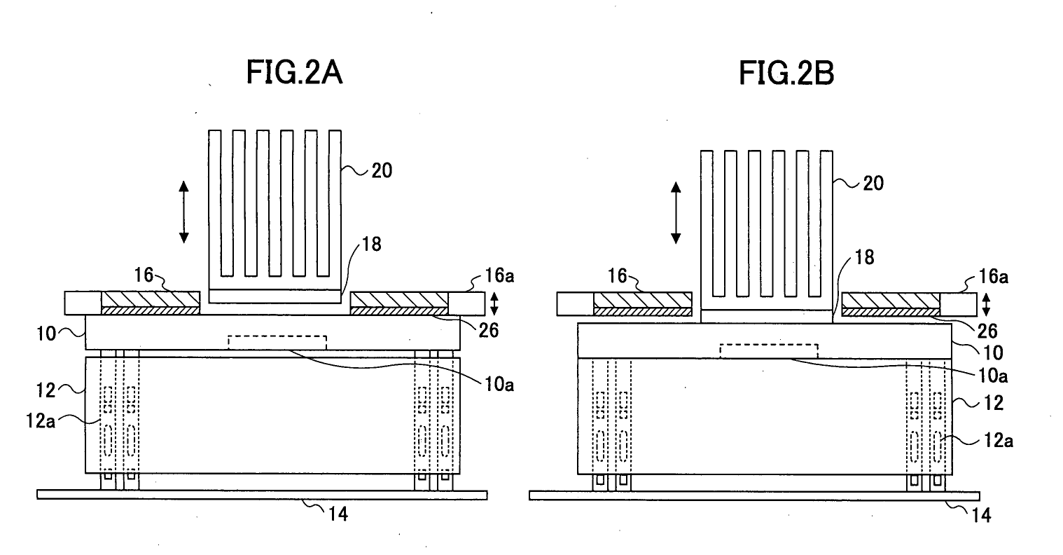

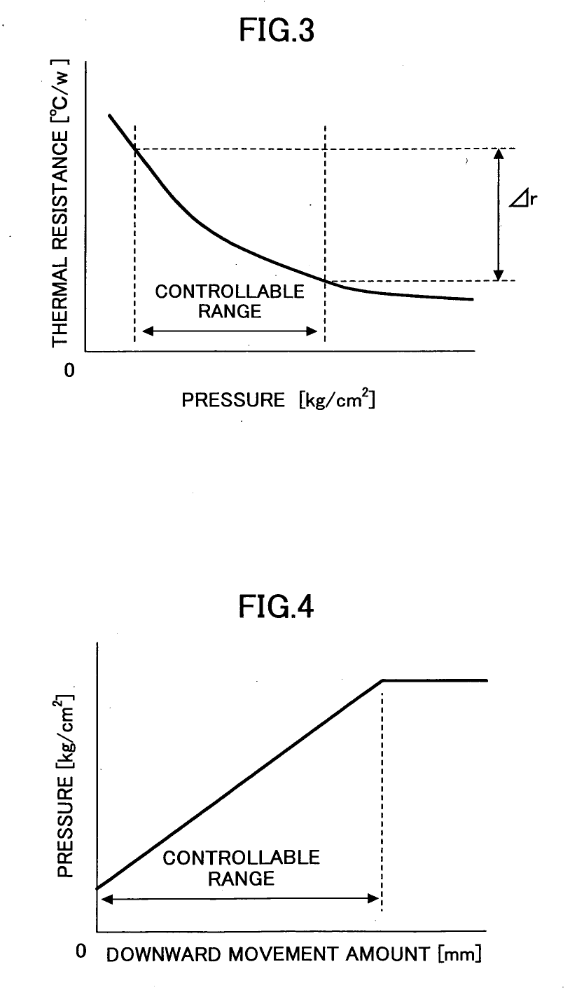

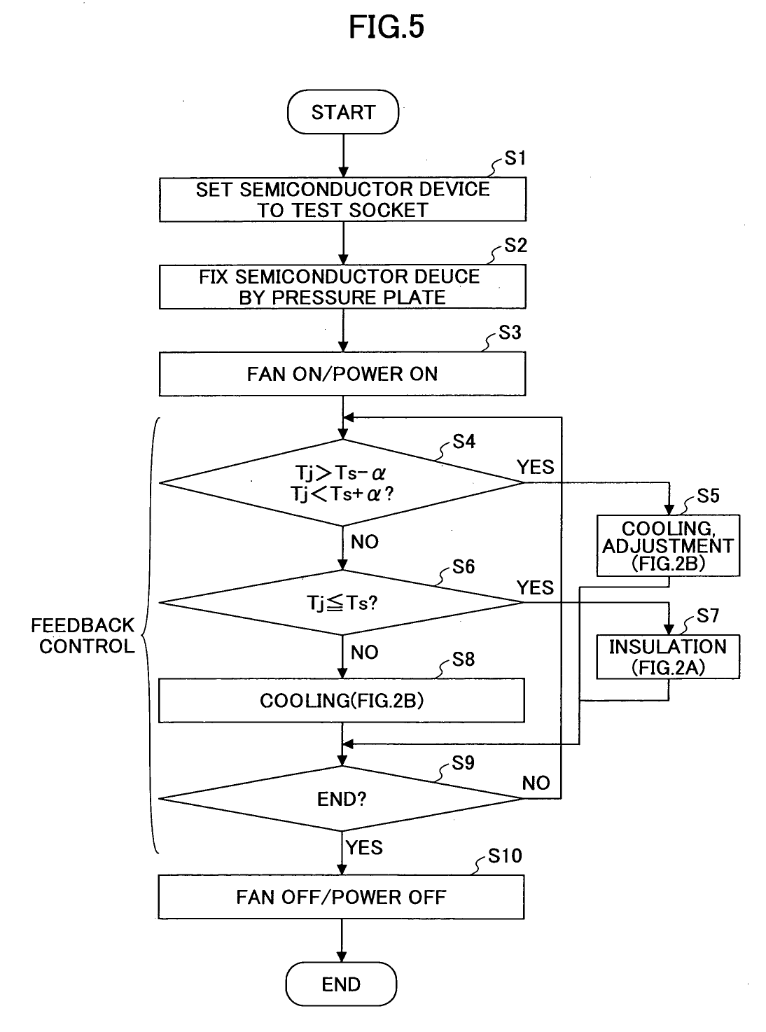

First, a description will be give, with reference to FIG. 1 and FIG. 2, of a temperature control apparatus of a semiconductor device according to the embodiment of the present invention.

FIG. 1 is a plan view showing an outline structure of the temperature control apparatus of a semiconductor device according to the embodiment of the present invention. FIG. 2 is a side view showing an outline structure of the temperature control apparatus shown in FIG. 1.

The temperature control apparatus shown in FIG. 1 and FIG. 2 is built into a test apparatus that performs an electrical characteristic test of the semiconductor device. The temperature control apparatus is configured and arranged to control the junction temperature Tj of the semiconductor device when performing the electric characteristic test.

The test apparatus has a test socket 12 equipped with contactors (probe pins) 12a that acquire electric conduction by contacting electrodes of a semiconductor device 10. The contactors 12a are connected to a test board 14 provided under the test socket 12 so that the semiconductor device 10 is electrically connected to a test circuit of the test board 14 through the contactors 12a.

The semiconductor device 10 is placed on the test socket 12, and the electrodes of the semiconductor device 10 can be brought into contact with contactors 12a by pressing the semiconductor device 10 onto the test socket 14 by a pressure plate 16. FIG. 2A shows a state where the semiconductor device 10 is pressed onto the test socket 12 by the pressure plate 16. It should be noted that support columns 16a are attached on four corners of the pressure plate 16, and an upward and downward moving mechanism (not shown in the figure) is provided to move the support columns 16a. By moving the support columns 16a up and down, the pressure plate 16 can be pressed against or separated from the semiconductor device 10. Although the support columns 16a extend downward from the pressure plate 16 in FIG. 2, illustration of the support columns 16a is omitted for the sake of simplification of the drawing.

The temperature control apparatus according to the present embodiment has a heat sink 20, which can contact a back surface of a package of the semiconductor device 10 via a thermal sheet 18. The heat sink 20 has a size which can cover an area directly above a semiconductor chip 10a arranged in the center of the semiconductor device 10. The heat sink 20 is movable up and down by the upward and downward moving mechanism (not shown). The thermal sheet 18 is attached to the heat sink 20 so as to move up and down together with the heat sink 20. In the state shown in FIG. 2A, the heat sink 20 is at an upper position, where the thermal sheet 18 is distant from the back surface of the semiconductor device 10. The thermal sheet 18 is provided for transferring heat of the semiconductor device 10 to the heat sink 20 as mentioned later.

A push fan 22 is arranged on one side of the heat sink 20, and a pull fan 24 is arranged on the opposite side. The push fan 22 is a cooling fan for cooling the heat sink 20 by causing a constant amount of air to flow toward the heat sink 20. The pull fan 24 is a cooling fan for suctioning the air heated by the heat sink 20 and discharging the suctioned air to outside. Although the heat sink 20 is subjected to the forced-air-cooling in the present embodiment, only one of the push fan 22 and the pull fan 24 may be used.

It should be noted that the push fan 22 and the pull fan 24 are controlled to operate in the state where heat sink 20 is moved down as shown in FIG. 2B and the thermal sheet 18 is in contact with the back surface of the semiconductor device 10 so as to cool the heat sink 20 by a constant air flow.

Here, in the present embodiment, a sheet-like thermal insulating material 26 is attached to the above-mentioned pressure plate 16. The sheet-like thermal insulating material 26 is attached to a surface of the pressure plate 16 being brought into contact with the semiconductor device 10 so that the back surface of the semiconductor device 10 is covered by the thermal insulating material 26 in a state (shown in FIG. 2A) where the pressure plate 16 is pressed against the semiconductor device 10.

Although any materials having a sheet-like shape and having a thermal insulating effect can be used as the thermal insulating material 26, it is preferable to use, for example, a sheet of Gore-tex (registered trade mark) having a high thermal insulating effect. Additionally, although the pressure plate 16 should be a plate-shaped rigid member which can press the semiconductor device 10, it is preferable that the pressure plate 16 itself is formed of a material having a thermal insulation characteristic, such as a bakelite or a resin.

As shown in FIG. 2A, when the back surface of the semiconductor device 10 is covered by the thermal insulating material 26, the heat generated in the semiconductor chip 10a in the semiconductor device 10 is not radiated from the back surface of the semiconductor device 10 and stays inside the semiconductor device 10. Thereby, the internal temperature of the semiconductor device 10 rises rapidly.

Conventionally, since the pressure plate 16 is formed of a material having a high heat transfer coefficient, such as, for example, an aluminum plate, the heat generated in the semiconductor device 10 is easily radiated to outside and it is difficult to raise the internal temperature of the semiconductor device 10 rapidly. However, by providing the thermal insulating material 26 to the pressure plate 16 as in the present embodiment, heat radiation from the semiconductor device 10 is suppressed, and, thereby, the internal temperature of the semiconductor device 10 can be rapidly raised by the self-heating of the semiconductor device 10.

A description will now be given more specifically of the above-mentioned thermal sheet 18. The thermal sheet 18 is formed of a heat transfer material having elasticity, and has a characteristic in which a thermal resistance changes according to a magnitude of a pressure. That is, the thermal sheet 18 has a characteristic in which a thermal resistance decreases as a pressure increases as shown in the graph of FIG. 3.

By moving heat sink downward and causes the thermal sheet 18 to contact the back surface of the semiconductor device 10 as shown in FIG. 2B, and further moving the heat sink 20 downward, the pressure applied to the thermal sheet 18 can be increased as shown in the graph of FIG. 4. Therefore, the thermal resistance of the thermal sheet 18 can be adjusted by adjusting an amount of downward movement of the heat sink 20. Accordingly, an amount of heat transferred to the heat sink 20 from the semiconductor device 10 through the thermal sheet 18 can be adjusted, and, thereby, an amount of cooling of the semiconductor device 10 is adjusted, which enables a control of the temperature of the semiconductor device 10.

It should be noted that if the heat sink 20 is moved downward and the thermal sheet 18 is pressed against the back surface of the semiconductor device 10 as shown in FIG. 2B, the semiconductor device 10 moves downward and is brought into contact with the test socket 12. Accordingly, the back surface of the semiconductor device 10 is separated from the thermal insulating material 26 of the pressure plate 16, and the heat insulation of the semiconductor device 10 is canceled. Thereby, the semiconductor device 10 comes to be efficiently cooled by the heat sink 20.

A description will now be given, with reference to FIG. 5, of a temperature control method of a semiconductor device according to the temperature control apparatus having the above-mentioned structure. FIG. 5 is a flowchart of a temperature control process of a semiconductor device performed by the above-mentioned temperature control apparatus.

First, the semiconductor device 10 is placed at a predetermined position on the test socket 12 (step S1). In this state, the electrodes of the semiconductor device 10 are in contact with the contactors 12a of the test socket 12. The heat sink 20 and the pressure plate 16 are at an elevated position and separated from the semiconductor device 10.

Next, the pressure plate 16 is moved downward so as to cause the thermal insulating material 26 of the pressure plate 16 to contact the back surface of the semiconductor device 10 and apply a pressure to the semiconductor device 10 (step S2). Thereby, the contactors 12a of the test socket 12 are pressed by the electrodes of the semiconductor device 10, which provides a contact pressure and the semiconductor device 10 is fixed. In this state, the semiconductor device 10 is not pressed completely against the test socket 12 and a gap is maintained between the semiconductor device 10 and the test socket 12 as shown in FIG. 2A. The contactors 12a of the test socket 12 are so-called pogopin-type contactors, which are configured to generate an appropriate contact pressure even in the state shown in FIG. 2A.

When pressing the pressure plate 16 against the semiconductor device 10, the back surface of the semiconductor device 10 is covered by the thermal insulating material 26 and in a thermally insulated state since thermal insulating material 26 is attached to the pressure plate 16.

Then, a power supply of the test apparatus is turned ON, and the push fan 22 and the pull fan 24 of the temperature control apparatus are operated (step S3). When the power supply of the test apparatus is turned on, electric power is supplied from the test board 14 to the semiconductor device 10 through the contactors 12a, and, thus, the semiconductor chip 10a in the semiconductor device 10 is activated and heat is generated. At this time, since the heat sink 20 is at the elevated position and separated from the semiconductor device 10, an operation for cooling the semiconductor device 10 is not performed. It should be noted that although the push fan 22 and the pull fan 24 may be operated at this moment, the push fan 22 and the pull fan 24 may be operated when a cooling operation is performed later since the cooling by the heat sink 20 is not performed.

After the power supply to the semiconductor device 10 is started, the internal temperature of the semiconductor device 10 rises due to self-heating. At this time, since the back surface of the semiconductor device 10 is covered and thermally insulated by the thermal insulating material 26, an amount of heat radiated from the semiconductor device 10 has been decreased, and, thereby, the internal temperature (junction temperature Tj) of the semiconductor device 10 rises rapidly. That is, the internal temperature of the semiconductor device 10 can be raised rapidly by mere the self-heating of the semiconductor device 10 without giving heat to the semiconductor device 10 from an external heater as is in a conventional method. The internal temperature Tj of the semiconductor device 10 can be estimated from a measurement value, for example, acquired by measuring a surface temperature of the semiconductor device 10 using a contact-type sensor or a non-contact-type sensor. Here, a target value of a test temperature when testing the semiconductor device 10 is set as a setting temperature Ts.

After the power supply to the semiconductor device 10 is started, it is determined whether the internal temperature Tj is higher than the setting temperature Ts−α or the internal temperature Tj is lower than the setting temperature Ts+α (step S4). That is, it is determined whether the internal temperature Tj falls within a range of the setting temperature Ts±α. Here, α is a permissible value to the setting temperature Ts.

If it is determined in step S4 that Tj>Ts−α and Tj<Ts+α (YES of step S4), it is determined that the internal temperature Tj is within the permissible range of the setting temperature Ts, and the temperature control process proceeds to step S5. In step S5, as shown in FIG. 2B, the heat sink 20 is moved downward to press the thermal sheet 18 onto the back surface of the semiconductor device 10 to cool the semiconductor device 10, and the internal temperature Tj is maintained around the setting temperature Ts while adjusting an amount of cooling by adjusting the pressure applied to the thermal sheet 18, and a test of the semiconductor device 10 is carried out. It should be noted that if the heat sink 20 is moved downward and the thermal sheet 18 is pressed against the back surface of the semiconductor device 10, the semiconductor device 10 moves downward from the position indicated in FIG. 2A, and the back surface of the semiconductor device 10 is separated from the thermal insulating material 26. Thereby, the heat insulation of the semiconductor device 10 is canceled and the semiconductor device 10 is cooled by the heat sink 20.

On the other hand, if it is determined in step S4 that Tj>Ts−α is not satisfied and Tj<Ts+α is not satisfied (NO of step S4), it is determined that the internal temperature Tj does not fall within the permissible range of the setting temperature Ts, and the temperature control process proceeds to step S6. In step S6, it is determined whether the internal temperature Tj is lower than the setting temperature Ts.

If it is determined in step S6 that Tj≦Ts (YES of step S5), it is determined that the internal temperature Tj has not reached the setting temperature Ts yet, and the temperature control process proceeds to step S7. As shown in FIG. 2A, the state where thermal insulation 26 is in contact with the back surface of the semiconductor device 10 is maintained in step S7 so as to let the rising of the internal temperature Tj due to the self-heating of the semiconductor device 10 continue.

On the other hand if it is determined in step S6 that Tj≦Ts is not satisfied (NO of step S5), it its determined that the internal temperature is equal to or higher than the setting temperature Ts+α, and the temperature control process proceeds to step S8. In step S8, the heat sink 20 is moved downward as shown in FIG. 2B so as to press the thermal sheet 18 against the back surface of the semiconductor device 10 and cool the semiconductor device 10 to cause the internal temperature Tj to drop.

Following the steps S5, S7 and S8, it is determined in step S9 whether the test of the semiconductor device 10 has ended. In steps S7 and S8, since the internal temperature Tj does not fall within the range of setting temperature Ts±α, the test of the semiconductor device 10 has not been performed. Therefore, the determination of step S9 at that time is negative (NO), and the temperature control process returns to step S4. On the other hand, since the test has been performed in step S5, the determination of step S9 is YES if the test has been ended, and the temperature control process proceeds to step S10.

In step S10, the power supply to the semiconductor device 10 is stopped (OFF), and the operation of the push fan 22 and the pull fan 24 of the temperature control apparatus is stopped (OFF), and the temperature control process is ended.

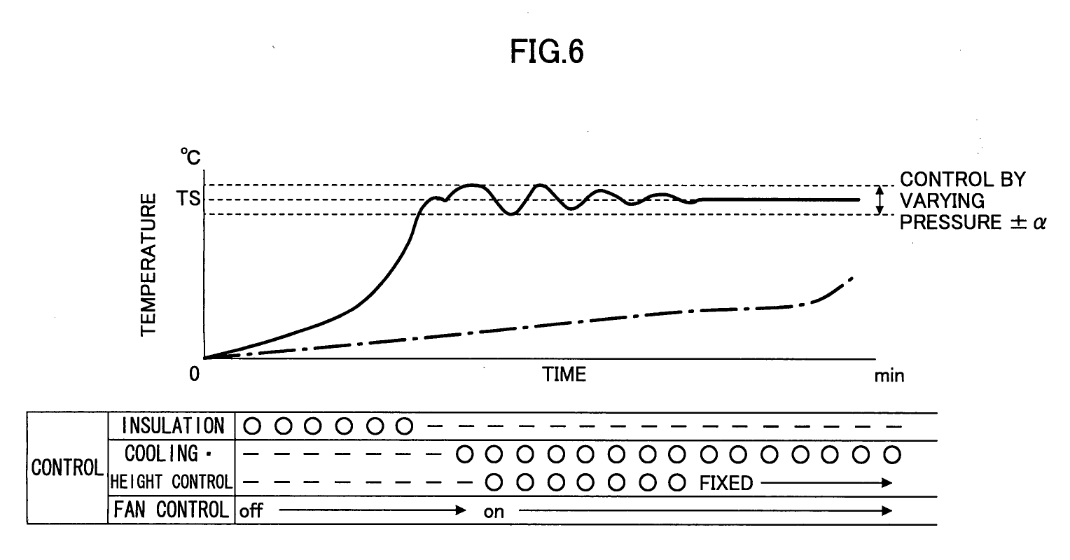

A description will now be given, with reference to FIG. 6, of an example of temperature change of the semiconductor device 10 when performing the above-mentioned temperature control processes. FIG. 6 is a graph showing changes in the internal temperature of the semiconductor device 10 according to the temperature control process.

It should be noted that in the graph of FIG. 6, a solid line indicates the temperature of the semiconductor device 10 and a single-dashed chain line indicates a temperature of the semiconductor device when the thermal insulation by the thermal insulating material 26 is not applied.

When a power supply to the semiconductor device 10 is started, the internal temperature Tj of the semiconductor device 10 begins to rise. Since the semiconductor device 10 is insulated by the thermal insulating material 26, the temperature rise is far more rapid than a case where the thermal insulation is not applied, and the internal temperature Tj reaches near the setting temperature Ts for a short period of time. when the internal temperature Tj of the semiconductor device 10 reaches the setting temperature Ts−α, the thermal insulating material 26 is separated from the semiconductor device 10 so that the thermal insulation is canceled. Although the temperature rise of the semiconductor device 10 becomes dull due to the cancellation of the thermal insulation, the temperature rise still continues and the internal temperature Tj approaches the setting temperature Ts.

When the internal temperature Tj of the semiconductor device 10 exceeds the setting temperature Ts and reaches Ts+α, the heat sink 20 is moved downward and the thermal sheet 18 is brought into contact with the back surface of the semiconductor device 10, and the thermal sheet 18 is pressed. Thereby, the cooling of the semiconductor device begins, and the internal temperature Tj of the semiconductor device 10 turns to drop. When the internal temperature Tj of the semiconductor device 10 becomes lower than the setting temperature Ts, an adjustment (height control) of the pressure to the thermal sheet 18 is started so as to decrease the pressure. At this time, the operation of the push fan 22 and the pull fan 24 is started (fan control ON), but the internal temperature Tj of the semiconductor device 10 turns rise again since the decrease in the amount of cooling due to the decrease in the pressure is larger.

Thereafter, the internal temperature Tj is adjusted only by the pressure adjustment of the thermal sheet. The internal temperature Tj gradually approaches the setting temperature Ts and when the internal temperature Tj becomes substantially equal to the setting temperature Ts, the pressure to the thermal sheet is fixed so that the internal temperature Tj is maintained at the setting temperature Ts.

As mentioned above, according to the temperature control process of the present embodiment, when a power supply to the semiconductor device 10 is started, the temperature of the semiconductor device 10 is rapidly raised due to the semiconductor device 10 being thermally insulated, and, thereby the setting temperature is reached in a short time. Additionally, since the internal temperature rise of the semiconductor device is achieved by the self-heating alone, there is no need to use a heater or the like for raising temperature, and there is no erroneous operation of the semiconductor device due to a switching noise of the heater or the like.

Moreover, for example, even when the semiconductor device 10 cannot reach the setting temperature Ts easily due to a variation in power consumption, the internal temperature can be compulsorily raised by the thermal insulation. In this case, the internal temperature Tj of the semiconductor device 10 may be controlled while applying the thermal insulation by the thermal insulating material 26 and simultaneously cooling by the heat sink 20 via the thermal sheet 18.

The present invention is not limited to the specifically disclosed embodiments, and variations and modifications may be made without departing from the scope of the present invention.

The present application is based on Japanese priority application No. 2006-145670 filed May 25, 2006, the entire contents of which are hereby incorporated herein by reference.

What is claimed is:

1. A temperature control method of a semiconductor device, comprising:
supplying an electric power to the semiconductor device while thermally insulating the semiconductor device by bringing a thermal insulating material into contact with the semiconductor device;
raising an internal temperature of said semiconductor device by internal-heating of said semiconductor device; and
separating said thermal insulating material from said semiconductor device when the internal temperature reaches a predetermined temperature.

2. The temperature control method as claimed in claim 1, wherein the internal temperature is adjusted while cooling said semiconductor device after separating said thermal insulating material from said semiconductor device.

3. The temperature control method as clamed in claim 1, further comprising:
pressing a heat sink onto said semiconductor device via a thermal sheet interposed therebetween after separating said thermal insulating material form said semiconductor device; and
adjusting the internal temperature by adjusting cooling of said semiconductor device by adjusting a pressure applied to the thermal sheet from the heat sink.

4. The temperature control method as claimed in claim 3, wherein the pressure applied to said thermal sheet is adjusted so that the internal temperature of said semiconductor device is maintained at a setting temperature, and the pressure by said heat sink is maintained constant after the internal temperature is maintained at the setting temperature.

5. A temperature control apparatus of a semiconductor device, comprising:
a pressure plate that is movable upward and downward with respect to the semiconductor device and configured to press said semiconductor device to a socket of a test apparatus;
a thermal insulating material attached to a surface of the pressure plate facing said semiconductor device; and
a heat sink that is movable upward and downward with respect to said semiconductor device and cools said semiconductor device by contacting said semiconductor device.

6. The temperature control apparatus as claimed in claim 5, wherein a thermal sheet is provided on a surface of said heat sink facing said semiconductor device, and said heat sink contacts and presses said semiconductor device via the thermal sheet.

7. The temperature control apparatus as claimed in claim 6, wherein said thermal sheet is a heat transfer member of which heat resistance changes when being elastically deformed by a pressure.

8. The temperature control apparatus as claimed in claim 5, further comprising a cooling fan for air-cooling said heat sink.

9. A test method of a semiconductor device, comprising:
supplying an electric power to the semiconductor device while thermally insulating the semiconductor device;
raising an internal temperature of said semiconductor device by internal-heating of said semiconductor device; and
separating said thermal insulating material from said semiconductor device when the internal temperature reaches a predetermined temperature.

10. The test method as claimed in claim 9, wherein the internal temperature is adjusted while cooling said semiconductor device after separating said thermal insulating material from said semiconductor device.

11. The test method as clamed in claim 9, further comprising:
pressing a heat sink onto said semiconductor device via a thermal sheet interposed therebetween after separating said thermal insulating material form said semiconductor device; and
adjusting the internal temperature by adjusting cooling of said semiconductor device by adjusting a pressure applied to the thermal sheet from the heat sink.

12. The temperature method as claimed in claim 11, wherein the pressure applied to said thermal sheet is adjusted so that the internal temperature of said semiconductor device is maintained at a setting temperature, and the pressure by said heat sink is maintained constant after the internal temperature is maintained at the setting temperature.

13. A test apparatus of a semiconductor device, comprising:
a pressure plate that is movable upward and downward with respect to the semiconductor device and configured to press said semiconductor device to a socket of the test apparatus;
a thermal insulating material attached to a surface of the pressure plate facing said semiconductor device; and
a heat sink that is movable upward and downward with respect to said semiconductor device and cools said semiconductor device by contacting said semiconductor device.

14. The test apparatus as claimed in claim 13, wherein a thermal sheet is provided on a surface of said heat sink facing said semiconductor device, and said heat sink contacts and presses said semiconductor device via the thermal sheet.

15. The test apparatus as claimed in claim 14, wherein said thermal sheet is a heat transfer member of which heat resistance changes when being elastically deformed by a pressure.

16. The test apparatus as claimed in claim 13, further comprising a cooling fan for air-cooling said heat sink.
